(19) United States
(12) Patent Application Publication
(10) Pub. No.: US 2026/0225877 A1
(43) Pub. Date: Aug. 6, 2026

(54) METHOD OF MANUFACTURING A MICROSTRUCTURE

(71) Applicant: MEMSSTAR LIMITED, Livingston Lothian (GB)

(72) Inventors: Anthony O'HARA, Livingston Lothian (GB); David ANDERSON, Livingston Lothian (GB); Toni SANDBRINK-KOBLENZ, Livingston Lothian (GB)

(21) Appl. No.: 19/151,014

(22) PCT Filed: Jan. 25, 2024
(86) PCT No.: PCT/GB2024/050197

§ 371 Date: Jul. 25, 2025

(30) Foreign Application Priority Data
Jan. 25, 2023 (GB) 2301066.3

(51) Int. Cl. B81C 1/00

(52) U.S. Cl. CPC B81C 1/00476; B81C 2201/0132; B81C 2201/0138

(57) ABSTRACT

A method of manufacturing a microstructure a microstructure with a three-dimensional structure is described. The method comprises performing an isotropic vapour etch of a sacrificial material. The etch parameters of the isotropic vapour etch are varied as a function of time responsive to (or based on) prior knowledge of the microstructure. The method has numerous advantages as can more efficiently create microstructures whilst minimising the risk of failure of the device.

The present invention relates to a method of manufacturing a microstructure. Typically, the microstructures are in the form of a semiconductor device or micro electromechanical systems (MEMS) that require the removal of a material relative to a substrate or other deposited material. In particular, this invention relates to an improved method for manufacturing a microstructure that employs an etching step.

### BACKGROUND TO THE INVENTION

### Semiconductor Manufacturing

Semiconductor manufacturing is a highly complex series of processes that uses multiple steps to construct a semiconductor device. However, at its most basic, it is the same method that is used to form all microstructure devices.

Manufacturing semiconductor devices, for example of the type depicted in FIG. 1 and represented generally by reference numeral 1, first typically comprises depositing a film 2 upon a substrate 3. Then, a photoresist layer 4 is deposited upon the film 2. The photoresist layer 4 is patterned using a photographic exposure followed by a developing and rinse phase. The resulting patterned photoresist layer 4 acts as a mask. After which, the exposed underlying film 2 is removed using an etch process. This is then repeated multiple times to construct the semiconductor device 1.

The etch process employed when manufacturing semiconductor devices is a low pressure plasma process called Reactive Ion Etching (RIE) that is ubiquitous in semiconductor manufacturing. RIE has a chemical component and a physical component. The chemical component of the etch is the rearrangement of a molecular structure by breaking existing molecular bonds and forming new molecular bonds. The physical component of the etch is a highly directional ion bombardment towards a surface of a semiconductor wafer to be etched.

FIGS. 1a and 1b depicts a semiconductor wafer 1 before an RIE etch process and FIGS. 1c and 1d depict the semiconductor device 1 resulting from the RIE etch process. A key feature of the method is that the RIE etch process is anisotropic, in other words, the etch is highly directional in the z direction and so essentially imparts the same pattern of the photoresist layer 4 in the x-y plane to the underlying film 2. Whilst the RIE etch process is a three-dimensional etch, the material removed is defined only by the progress in the z-direction. Therefore, a key variable used to describe the etch process is an etch rate, as measured in μm per minute, a one-dimensional unit.

The etch process is dependent on various parameters such as gas flow, pressure, temperature, and plasma power. Experimentation is performed to optimise the parameters, in other words the etch set-up, to provide a suitable etch rate. The film 2 comprises an exposed surface area 5 which is not covered by the photoresist layer 4 and so exposed to the etchant. The exposed surface area 5, also referred to as the etch front, is constant during the described anisotropic RIE etch process and so the optimised parameters are suitable for the duration of the RIE etch process. As such, when manufacturing semiconductors the parameters for the etching process generally do not change over time and so the etch process can be deemed as a one step process.

There are some exceptions as the etch parameters may vary to, for example, overcome an initiation surface layer or to fine tune the existing etch process.

When etching polysilicon there is an initial native oxide layer that must be removed from the surface of the exposed polysilicon layer. The chemical component of the RIE is optimised to etch silicon and therefore is not optimised to etch through the native oxide that has grown on the exposed polysilicon surface. In order to quickly get through the native oxide there is a breakthrough step that is added prior to the primary polysilicon etch. This so-called breakthrough step biases the etch to have more of the physical component so that the ion bombardment sputters the native oxide from the surface. This two-step etch is a short breakthrough step followed by the main RIE etch where the process parameters are all fixed.

Deep Reactive Ion Etching (DRIE) uses the Bosch process, as described in U.S. Pat. No. 5,501,893A, where the etch process cycles between an etch step and a polymerization step. This process facilitates the formation of deep structures within a film 2 having vertical edges, such as a trench with a horizontal surface corresponding to the base of the trench, and vertical surfaces corresponding to the sides of the trench. During the polymerization step a polymer layer is applied to the exposed vertical and horizontal surfaces. The polymer layer protects surfaces from the chemical component of the DRIE. However, during the DRIE process the physical component breaks through the polymer layer on the horizontal surface and not the polymer layer on the vertical surfaces. As such, the polymerization step effectively increases the unidirectional nature, in other words the anisotropy, of the DRIE process.

Although this DRIE process is a cyclic two-step process, during the etch step the etch parameters generally do not change. It is noted that as the DRIE process proceeds and the structure gets deeper, the depth of the trench has an effect on the etch step. It is noted that the original etch parameters are fine-tuned to ensure the etch rate remains stable as the etch step proceeds, as described in European Patent EP 0 822 584 B1. Yet, the profile of the structure remains the same and so such an etching process is still considered one-dimensional.

### MEMS Manufacture

Manufacturing of MEMS devices, such as that depicted in FIG. 2 and represented generally by numeral 6, is similar to that of the manufacturing of semiconductor devices 1, in that these methods predominantly uses all of the same processing techniques.

However, one process that is currently unique to the manufacture of MEMS devices 6 is a release etch process, also referred to as a sacrificial etch process.

A sacrificial layer 7 is initially deposited on a substrate 3 in the construction of the MEMS device 6 and then subsequently removed with an etch process, which allows the released structure 8 to operate as designed, for example, as a micromirror, accelerometer or microphone. In some MEMS devices 6 this etch process is to produce a cavity which provides, for example, thermal isolation from the substrate 3 below.

The structure of the sacrificial layer 7 to be etched and the access of the etchant to interact with the sacrificial later 7 it is very dependent on the MEMS device 6 being manufactured. There is very little commonality between different MEMS device 6 structures. The ideal etch process in this instance is isotropic with equal etching in all directions. Furthermore, it is desirable that the etchant does not react with the other materials within the MEMS device 6 and so is very selective.

The release etch process was initially performed using wet etching with the samples emersed into a bath of chemical etchant. Clearly with this method there is limited control of the etch process because it is simply determined by temperature and etchant concentration. Another issue that arises with wet etching is the danger of stiction. As the liquid is removed, surfaces of the release structure 8 can be pulled together due to the capillary action and if these surfaces come together there is a very large attractive force that holds these surfaces together.

Greater process control is achieved using vapour phase etch systems. The first systems using this approach were very basic and employed a pulsed approach wherein gases flow into a vacuum chamber, the chamber pressure rises to a pre-determined target and the chamber is left at this pressure either with the gases still flowing or completely sealed. This procedure is then repeated multiple times to etch to completion. Again, there is very little control of the etch process and the same parameters for the etch process are generally used for all different MEMS device structures.

One of the most common materials used as the sacrificial layer 7 is silicon dioxide that is etched using a hydrogen fluoride (HF) vapour, see for example UK patent number GB 2,487,716 B. An HF vapour etch is a plasma-less chemical etch which isotopically etches silicon dioxide and is described by the reaction equations:

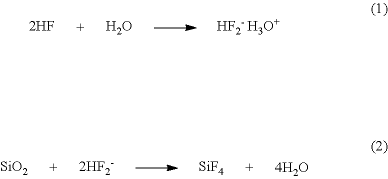

The water (H₂O) is found to ionise the HF vapour, as described by equation (1), and the ionised HF vapour (HF₂⁻) then etches the silicon dioxide (SiO₂), with the water (H₂O) acting as a catalyst. From equation (2), it is clear that water (H₂O) is also generated from the etching reaction itself.

It is universally accepted that for HF vapour etching to proceed, with a usable etch rate, say greater than 30 nm/min, a condensed fluid layer 9 is required to be present on the surface to be etched, see for example Journal of Vacuum Science and Technology A, 10 (4) July/Aug 1992 entitled “Mechanisms of the HF/H₂O vapor phase etching of SiO₂” in the name of Helms et al. Of all the compounds associated with the above described HF vapour etching process, water (H₂O) has the lowest vapour pressure and therefore forms the basis of the condensed fluid layer 9.

As will be appreciated from equation (2), H₂O is a by-product of the etch but also has an influence on the etch rate by contributing to the condensed layer 9 that has formed. The amount of etching taking place and subsequently the amount of H₂O being generated by the etch must be taken into account when controlling the etch process.

European patent number EP2046677 B1 discloses how control of the formation and composition of the condensed fluid layer 9 is key to managing the HF vapour etching of silicon dioxide. Precise etch control is achieved by performing the HF etch in a vacuum chamber, controlling the chamber pressure, temperature and the gas flows into the chamber. Other parameters that influence the HF vapour etch are the composition of the silicon dioxide layer being etched and the method of its deposition. For example, whether the silicon dioxide of the sacrificial layer 7 is produced by thermal oxidation or plasma enhanced chemical vapour deposition (PECVD). The denser the silicon dioxide, the slower the etching process for the same etching parameters.

### SUMMARY OF THE INVENTION

It is therefore an object of an embodiment of the present invention to provide a more efficient method of producing a microstructure when as compared to those techniques known in the art.

According to a first aspect of the present invention, there is provided a method of manufacturing a microstructure,
the method comprising performing an isotropic vapour etch of a sacrificial material, wherein etch parameters of the isotropic vapour etch are varied as a function of time responsive to (or based on) prior knowledge of the microstructure.

Preferably, the prior knowledge of the microstructure comprises prior knowledge of changes in area, and or location, and or direction of an etch front of the isotropic vapour etch.

Alternatively, or additionally, the prior knowledge of the microstructure comprises prior knowledge of compositional variation in the sacrificial material being etched.

Preferably, the isotropic vapour etch comprises a first phase at a first set of etch parameters for a first period of time to etch the sacrificial material at a first volumetric etch rate.

Preferably, the isotropic vapour etch further comprises a second phase at a second set of etch parameters for a second period of time to further etch the sacrificial material at a second volumetric etch rate.

Preferably, the first and second volumetric etch rates are dependent on different features of the microstructure.

Preferably, the first set of etch parameters are different to the second set of etch parameters.

Optionally, the etch parameters varied between first and second phases comprise pressure, gas flow rates, gas flow ratios, gas species and or temperature.

Optionally, the first period of time is different to the second period of time.

Preferably, the first volumetric etch rate and the second volumetric etch rate are maintained below a threshold value.

Optionally, the first and second volumetric etch rates are maintained below a threshold value by fixing the first and second etch parameters from the outset such that the highest possible etch rate is below the threshold value.

Alternatively, the first and second volumetric etch rates are maintained below a threshold value by changing the first and second etch parameters during the isotropic vapour etch such that the etch rate is below the threshold value.

Optionally, the first etch parameters may be dynamically varied during the first etch phase. Similar, second etch parameters may be dynamically varied during the second etch phase. This dynamic variation of the etch parameters can be considered fine-tuning the etch parameters to compensate for changes in the etch front.

Preferably, the first phase of the isotropic vapour etch may correspond to removing sacrificial material not covered by a mask layer. The sacrificial material is removed predominantly in a z direction.

Preferably, the second phase of the isotropic vapour etch may correspond to removing sacrificial material under the mask layer. The sacrificial material is removed predominantly in an x-y direction. The second phase of the isotropic vapour etch may be considered an undercut phase or a release phase.

Preferably, the isotropic vapour etch further comprises a third phase at a third set of etch parameters for a third period of time to further etch the sacrificial material at a third volumetric etch rate.

Preferably, the third phase of the isotropic vapour etch may correspond to removing further sacrificial material under the mask layer. The sacrificial material is removed predominantly in an x-y direction. The third phase of the isotropic vapour etch may be considered a deeper undercut phase.

Alternatively, the second phase of the isotropic vapour etch may correspond to removing sacrificial material with a different density or readiness to etching in comparison to the sacrificial material removed in the first phase of the isotropic vapour etch.

Alternatively, the first phase of the isotropic vapour etch may correspond to removing sacrificial material in a reaction limited etching regime. There may be a relatively small amount of sacrificial material to be etched.

Preferably, the first etch parameters comprise a relatively high etchant partial pressure by operating with a lower carrier gas flow and higher chamber pressure.

Preferably, the second phase of the isotropic vapour etch may correspond to removing sacrificial material in a transport limited etching regime. There may be a relatively large amount of sacrificial material to be etched.

Preferably, the second etch parameters comprise a relatively high etchant flow.

Preferably, the first and second phases of the isotropic vapour etch comprises substantially the same or similar volumetric etch rate. Advantageously, the two phase process maintains a practical volumetric etch rate as the etching regime transitions from reaction to transport limited.

Preferably, the isotropic vapour etch comprises a plurality of phases, each phase corresponding to an incremental change in the etch parameters and or period of time.

Preferably, the etchant may be HF vapour and the sacrificial material may be silicon dioxide. Alternatively, the etchant may be XeF₂ and the sacrificial material may be silicon.

Additionally, the method may further comprise monitoring the etch conditions with an etch monitor.

Preferably, the method may further comprise dynamically controlling the etch process by means of feedback from the etch monitor and or prior knowledge of the three-dimensional structure.

Preferably, the microstructure may be a semiconductor device, a CMOS Semiconductor, a MEMS device, a MEMS microphone or a microchannel.

According to a second aspect of the present invention, there is provided a microstructure manufactured in accordance with the method of the first aspect of the present invention.

Embodiments of the second aspect of the invention may include one or more features of the first aspect of the invention or its embodiments, or vice versa.

According to a third aspect of the present invention, there is provided a method of manufacturing a microstructure with a three-dimensional structure,
the method comprising performing an isotropic vapour etch of a sacrificial material, wherein the isotropic vapour etch comprises two or more phases in response to a variation in the three-dimensional structure of the microstructure which controls the volumetric etch rate responsive to (or based on) changes in the etch front and or compositional variation in sacrificial material.

Embodiments of the third aspect of the invention may include one or more features of the first and or second aspects of the invention or its embodiments, or vice versa.

According to a fourth aspect of the present invention, there is provided a method of manufacturing a microstructure,
the method comprising performing an isotropic vapour etch of a sacrificial material, wherein the isotropic vapour etch comprises two or more phases in which the volumetric etch rate in each phase is selected (or pre-selected) responsive to (or based on):
(a) changes in the etch front resulting from variations in the three-dimensional structure of the microstructure; and or
(b) compositional variation in the sacrificial material being etched.

The microstructure preferably comprises a three dimensional structure. The changes in the etch front and/or the compositional variation are preferably known prior to carrying out the method or anticipated while carrying out the etch.

Embodiments of the fourth aspect of the invention may include one or more features of the first and or second aspects of the invention or its embodiments, or vice versa.

### BRIEF DESCRIPTION OF THE DRAWINGS

There will now be described, by way of example only, various embodiments of the invention with reference to the drawings, of which:

FIG. 1 presents:
(a) a perspective view and (b) a schematic representation of a semiconductor wafer before a one dimensional etch process known in the art; and
(c) a perspective view and (d) a schematic representation of a semiconductor device after a one dimensional etch process known in the art.

FIG. 2 presents a schematic representation of a MEMS wafer before an HF vapour etch known in the art;

FIG. 3 presents a schematic representation of an etching apparatus in accordance with the present invention;

FIG. 4 presents:
(a) a perspective view and (b) a schematic representation of a MEMS wafer before a three-dimensional isotropic vapour etch in accordance with the present invention;
(c) a perspective view and (d) a schematic representation of the MEMS wafer during a first phase of the three-dimensional isotropic vapour etch;
(e) a perspective view and (f) a schematic representation of the MEMS wafer during a transition from the first phase to a second phase of the three-dimensional isotropic vapour etch; and
(g) a perspective view and (h) a schematic representation of the MEMS device after the second phase of the three-dimensional isotropic vapour etch.

FIG. 5 presents:
(a) a schematic representation of a MEMS microphone after a first phase of a three-dimensional isotropic vapour etch in accordance with the present invention;
(b) a schematic representation of the MEMS microphone after a second phase of the three-dimensional isotropic vapour etch; and
(c) a schematic representation of the MEMS microphone after a third phase of the three-dimensional isotropic vapour etch process.

FIG. 6 presents a schematic representation of a Complementary Method-Oxide-Semiconductor (CMOS) sensor before a multiple phase isotropic vapour etch in accordance with the present invention;

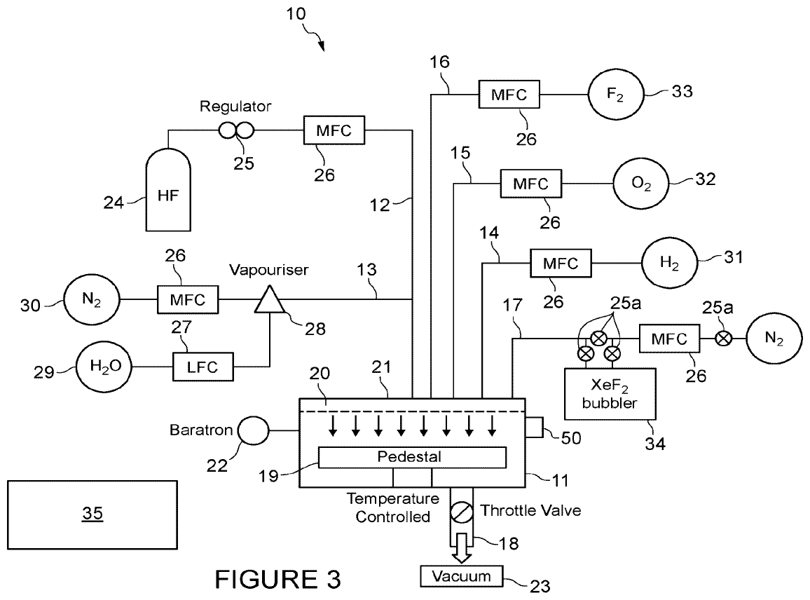

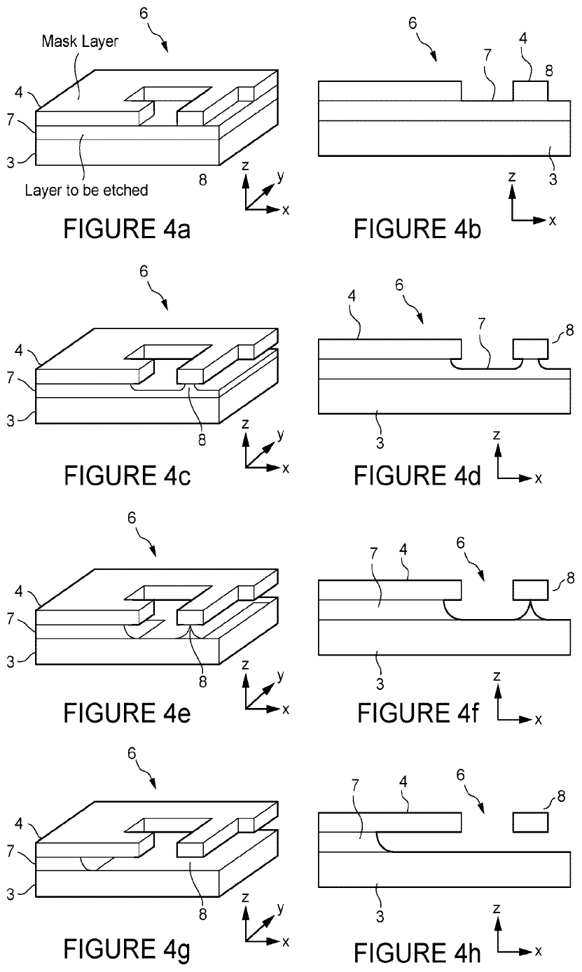

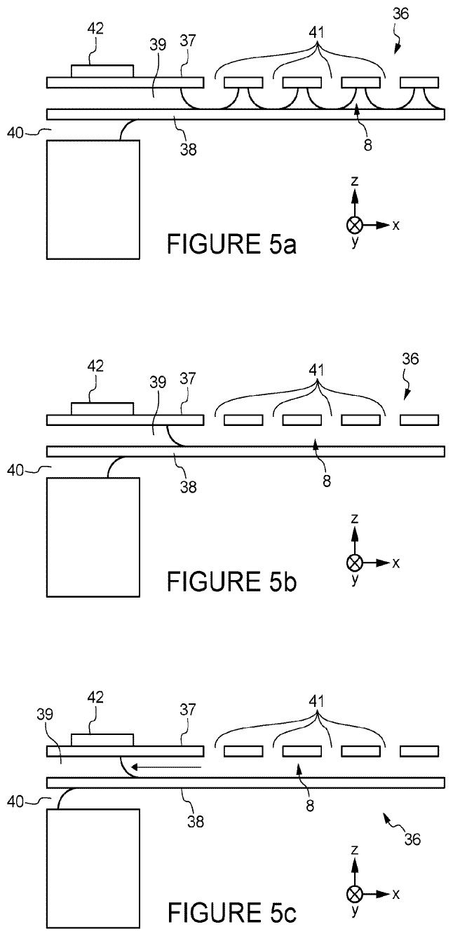

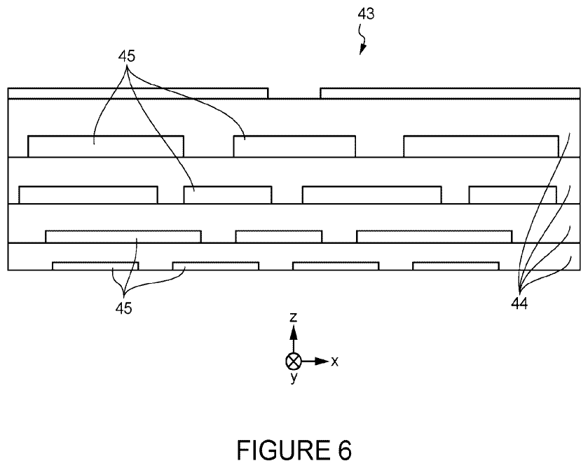

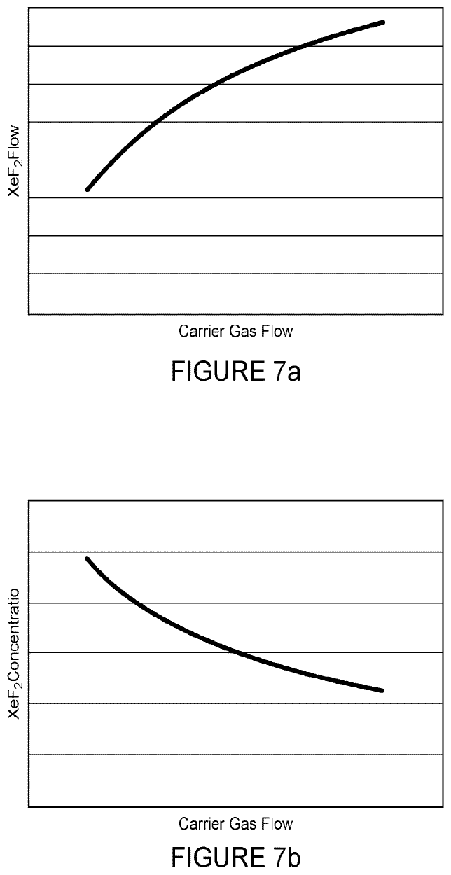

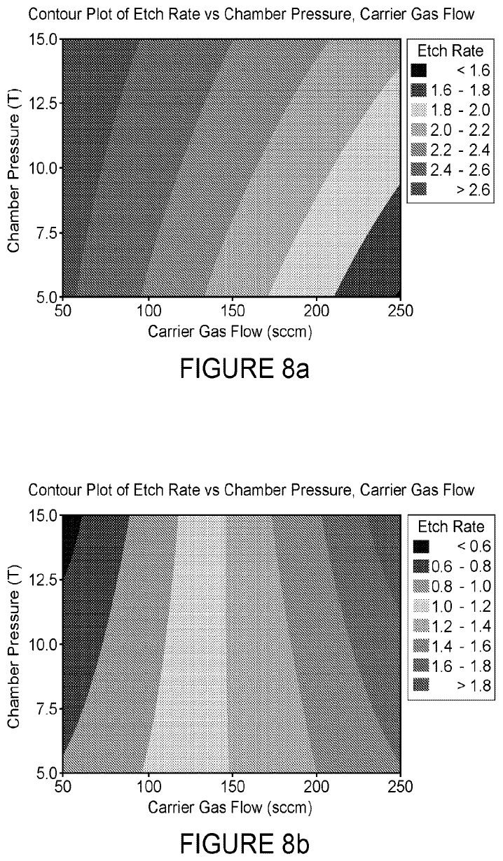

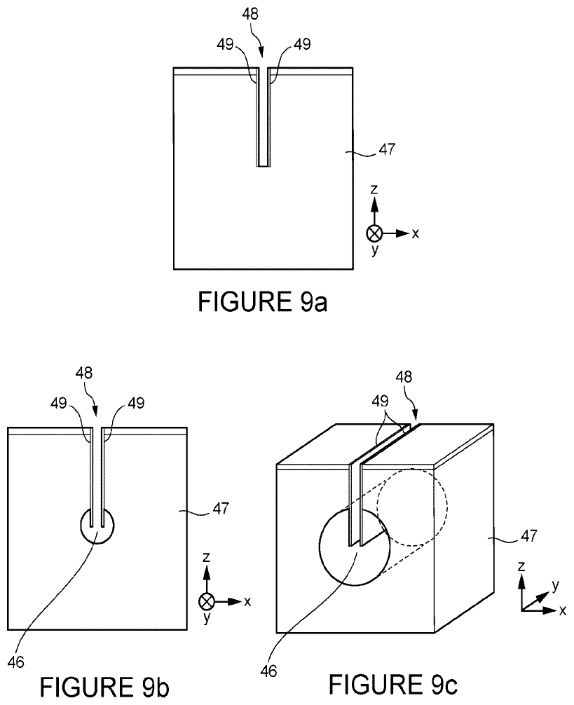

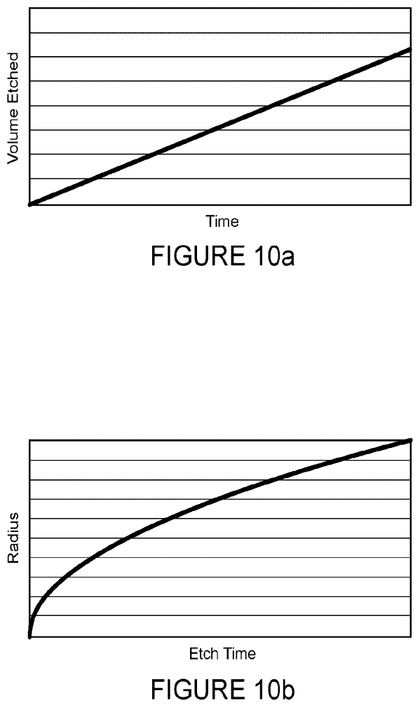

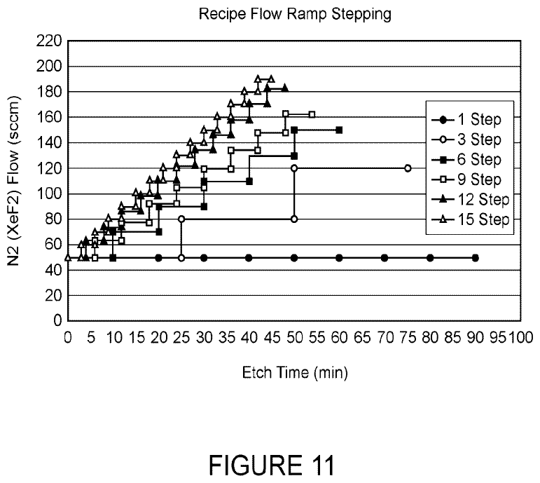

FIG. 7 presents a plot of (a) XeF₂ flow as a function of carrier gas flow and (b) XeF₂ concentration as a function of carrier gas flow exhibited within the etching apparatus of FIG. 3;

FIG. 8 depicts a contour plot of the etch rate as a function of chamber pressure and carrier gas flow for a (a) reaction limited etch regime and (b) a transport limited etch regime;

FIG. 9 depicts perspective views of a microchannel
(a) before an isotropic vapour etch in accordance with the present invention;
(b) during a first phase of the isotropic vapour etch which is reaction limited; and
(c) during a second phase of the isotropic vapour etch which is transport limited.

FIG. 10 depicts a plot of (a) the volume etched as a function of time and (b) the radius of as a function of time when manufacturing the microchannel of FIG. 9;

FIG. 11 depicts the carrier gas (N₂) flow as a function of etch time for a process recipe comprising 1 (grey), 2 (yellow), 3 (orange), 9 (green), 12 (blue) and 15 (pink) steps in the carrier gas flow when manufacturing the microchannel of FIG. 9.

In the description which follows, like parts are marked throughout the specification and drawings with the same reference numerals. The drawings are not necessarily to scale and the proportion of certain parts have been exaggerated to better illustrate details and the features of embodiments of the invention.

### DETAILED DESCRIPTION OF PREFERRED EMBODIMENTS

An explanation of the present invention will now be described with reference to FIG. 3 to

### Etching Apparatus

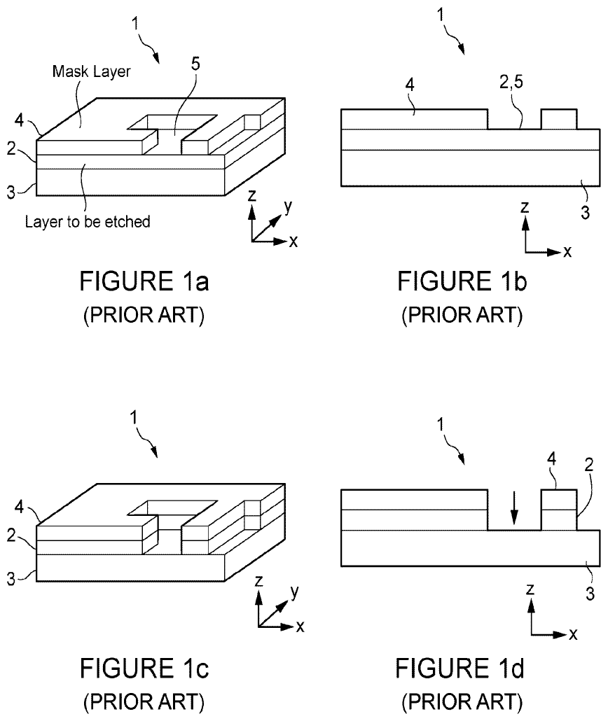

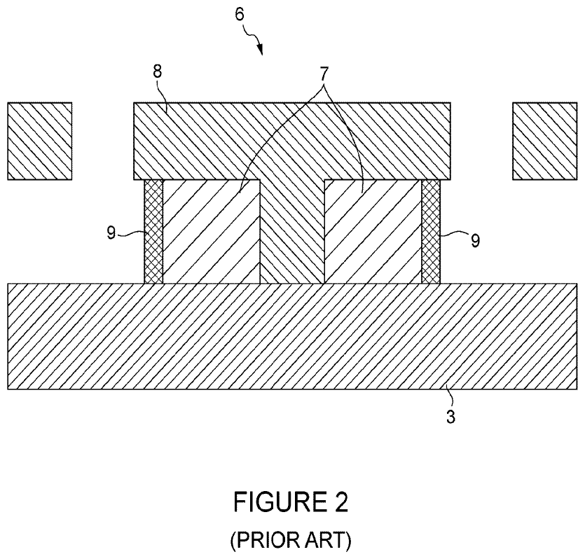

FIG. 3 presents a schematic representation of an etching apparatus 10 suitable for etching a microstructure, such as the semiconductor device 1 of FIG. 1 or the MEMS device 6 of FIG. 2. The etching apparatus 10 of FIG. 3 is suitable for various etching processes. Although it will be understood that separate etching apparatus may be provided for different etching processes. The etching apparatus 10 can be seen to comprise an etching chamber 11 attached to which are six input lines 12, 13, 14, 15, 16 and 17, and an output vacuum line 18.

Within the etching chamber 11 is a temperature controlled pedestal 19 suitable for locating the wafer 1, 6 to be etched within the etching chamber 11. Fluids supplied from the six input lines 12, 13, 14,15, 16 and 17 enter the internal volume of the etching chamber 11 via a fluid injection system 20 located within a lid 21 the etching chamber 11.

The pedestal 19, upon which the microstructure 1, 6 is located, can be set and maintained at a pedestal temperature Tₚ, by a temperature controller. This temperature may be above or below room temperature, the particular temperature being selected to optimise the etching process (typically 5-25° C.). In addition, during the etching process the walls of the etching chamber 11 are heated, typically to around 20-70° C.

The pressure of the etchant gas within the etching chamber, P_{c}, is monitored by a chamber pressure controller 22. The pressure controller 22 also incorporates a gas flow controller employed to provide a means of controlling the pressure within the etching chamber 11 by controlling the operation of a vacuum pumping system 23 located on the output vacuum line 18.

HF vapour 24 is controllably supplied to the etching chamber 11 by the first input line 12 through a regulator 25 and a first mass flow controller (MFC) 26.

Controlled quantities of water are supplied to the etching chamber 11 by the second input line 13. In particular, a liquid fluid controller (LFC) 27 and vaporiser 28 located within the second input line 13 is employed to produce controlled levels of water vapour from a water reservoir 29. A flow of nitrogen from a nitrogen gas source 30 through to the vaporiser 28 is controlled by a second MFC 26. The nitrogen carrier gas is employed to transport water vapour to the internal volume of etching chamber 11 via the fluid injection system 20.

The third 14, fourth 15 and fifth 16 input lines provide means for connecting additional gas sources 31, 32 and 33 e.g. hydrogen (H₂), oxygen (O₂) or fluorine (F₂) to the internal volume of the etching chamber 11. Control of these gas flows is again provided by mass flow controllers (MFC) 26.

Xenon Difluoride (XeF₂) vapour is controllably supplied to the etching chamber 11 by the sixth input line 17 which comprises a XeF₂ bubbler 34 and a nitrogen gas source 30. The XeF₂ bubbler 34 comprises XeF₂ crystals. As nitrogen gas passes over the XeF₂ crystals, XeF₂ sublimes and is carried by the nitrogen gas into the etching chamber 11. A mass flow controller (MCF) 26 in combination with pneumatic valves 25a controls: the supply of nitrogen gas to the XeF₂ bubbler 34; the supply of nitrogen gas to the etching chamber 11; and the supply of nitrogen gas with XeF₂ to the etching chamber 11. The pump rate of the vacuum pumping system 23 and or the MCF 26 can be controlled, for example by pump control valve, to maintain a set operating pressure with the etching chamber 11.

A computer controller 35 is employed to automate the regulation of the various components and parameters of the etching chamber 11, e.g. the supply of nitrogen carrier gas, HF vapour, chamber temperatures and pressure etc.

When manufacturing semiconductor devices 1 such as that depicted in FIG. 2, the applicant has discovered the surface area of the sacrificial layer 7 exposed to the etchant, in other words the etch front, can influence the etch rate. For example, the area and or location and or direction of the etch front can influence the etch rate. Specifically, an etch front with a large area etches faster than an etch front with a small area because the etch front with the larger area generates more H₂O by-product which in turn contributes to the condensed layer 9.

As the sacrificial etch proceeds the etch front will change depending on the structure being etched. The change in the etch front can be very dramatic. Properties of the etch front such as the area and or location and or direction of the etch front can change. As the etch front changes the etch rate also changes. So, with no change in the parameters of the etch process, the etch rate will change depending on the surface being etched or a change in silicon dioxide material encountered, such as the density or readiness to etching.

If the area of the etch front reduces or the silicon dioxide material becomes denser the etch rate can decrease to a point that is not practical to continue. If the area of the etch front increases or the etch front encounters a less dense oxide the etch rate will increase. Very high etch rates can cause issues such as stiction and metal corrosion.

Clearly the etch rate must be controlled to produce a robust etch as the etch proceeds through the structure. However, operating the etch process in a one dimensional manner and considering the etch rate in μm per minute is inefficient for a three dimensional structure, such as the release structure 8 of a MEMS device 6. In other words, operating the etch process in a single temporal phase and not considering predefined, known or anticipated changes in the microstructure, namely changes to the etch front and or compositional variation of the sacrificial material which will change the etch rate, is inefficient.

### Method of Etching

The present invention relates to a method of manufacturing a microstructure with a three-dimensional structure. Various examples of this method are depicted in FIGS. 4 to 11 and described in detail below.

In general, all of these examples relate to a method comprising performing an isotropic vapour etch of a sacrificial material. This isotropic vapour etch comprises two or more temporal phases in which the volumetric etch rate in each phase is selected (or pre-selected) responsive to (or based on) prior knowledge of the microstructure. Specifically, the prior knowledge of the microstructure may comprise (a) prior knowledge of changes in the area, and or location and or direction of the etch front of the isotropic vapour etch and or (b) prior knowledge of compositional variation in the sacrificial material being etched. The terms prior knowledge and predetermined are used interchangeably herein. Specifically, these terms refer to information which is known before commencement of the isotropic vapour etch, by virtue of knowing what the microstructure is.

The volumetric etch rate is determined, and can be controlled, by the etch parameters. As such, the method can also be expressed in terms of the etch parameters. Specifically, the isotropic vapour etch comprises varying the etch parameters of the isotropic vapour etch as a function of time responsive to (or based on) prior knowledge of the microstructure. The terms chamber parameters and etch parameters are used interchangeably herein.

The method in accordance with the present invention is very different to, for example, the standard RIE etching process for a semiconductor as described above. The RIE etching process is one-dimensional as for example, the area and direction of the etch front does not change as the etch progresses. Whereas the method in accordance with the present invention is three-dimensional. As such, the method in accordance with the present invention needs to be viewed and described in a very different manner to that known in the art.

Significantly, the isotropic vapour etch process is very dependent on the three-dimensional structure. As the etch process proceeds the etch front and or density of the sacrificial material will change. Consequently, optimised etch parameters for a first phase of an etch will not, therefore, be optimum for a second phase of an etch, where different phases correspond to the etching of different features of the three-dimensional structure. Ideally, to achieve an optimised etching process for the full release of a microstructure and or to maintain a practical etch rate, the etch parameters must change as the etch process proceeds to accommodate the change in structure.

The method in accordance with the present invention is performed in the vacuum chamber 11 of the etching apparatus 10 depicted in FIG. 3. The etch parameters are all precisely controlled. The sample temperature, gas flows and chamber pressure are all accurately controlled and can be adjusted to optimise the vacuum chamber 11 set-up to maximise the etch as the etch process proceeds. The vacuum chamber 11 conditions are controlled using software, where the vacuum chamber 11 control parameters are set using a series of control steps. This series of control steps is normally referred to as a process recipe. To summarise, the chamber parameters or set-up represent the etching process at a single time point or uniform phase, whereas a process recipe represents how the chamber parameters change from start to finish of the etching process.

It will be appreciated that there are numerous vapour phase isotropic etches that are all relevant to the present invention. The control of these different etches can be optimised by varying the chamber parameters, alternatively termed etch parameters. The chamber parameters may be different for the different etches. As examples, we describe below the conditions for two specific etches, namely an HF vapour etch and an XeF₂ etch.

First, in the context of an HF vapour etch, the etch rate is set by the creation and control of the condensed layer that forms on the exposed surface 5 of the sacrificial material 7. The least volatile compound in the chamber is H₂O and the condensed layer formation is tied to the vapour pressure of H₂O.

Temperature is a control parameter that is very difficult to change quickly and is generally set through-out the etch process.

The gases used in the etching process, for example are HF, N₂ and H₂O and the ratio of these gases determines the etch rate at a certain pressure. Gas flow changes can be performed quickly and used to make small etch rate changes. The gas flows are precisely controlled using Mass Flow Controller (MFCs) 26.

The primary control parameter is pressure. The pressure is accurately controlled by the vacuum pumping system 23, and specifically a throttle valve, on the output vacuum line of the etching chamber 11. The pressure is ramped to target value and then precisely controlled.

### Example 1—SOI Wafer Etch

A common substrate 3 used for the manufacture of a MEMS device 6 is Silicon on Insulator (SOI) wafers. There are different manufacturing methods to generate the SOI wafers, but they all result in a single crystal silicon layer 4 on top of an oxide layer 7 with a silicon substrate 3 below. The top layer of silicon 4 is patterned and so acts as a mask when creating the MEMS device 6. The oxide layer 7 is a sacrificial layer which is etched to release a structure 8.

The initial structure of the MEMS device depicted in FIGS. 4a and 4b is the same of the arrangement for a standard semiconductor RIE etch depicted in FIG. 1. However, as the oxide etch proceeds a very different etch process occurs.

The etch process as depicted in FIG. 4 is an isotropic vapour etch process as opposed to an anisotropic process as depicted in FIG. 1. In other words, the etch process depicted in FIG. 4 comprises a lateral component and the etch proceeds in three dimensions. The etch front changes during the etch process. Specifically, the area, location and direction of the etch front changes. FIGS. 4c and 4d, show the area of the etch front increases due to an increase in the area of the oxide layer exposed to the etchant. This has an influence on the etch as the etch rate increases as the etch proceeds.

The etch rate needs to be maintained below a certain threshold to ensure issues such as stiction or metal corrosion do not occur. This can be done by controlling the etch parameters in two ways.

First, the chamber pressure can be set such that as the etch process proceeds, the highest etch rate that is encountered is below the threshold that issues would occur.

Alternatively, the etch process can be initiated at a higher chamber pressure to have a relatively high etch rate. As the etch process proceeds, the etch rate increases, as the etch front expands into the microstructure 6. The chamber parameters are changed to keep the highest etch rate below the threshold that issues would occur. This can be achieved by lowering the chamber pressure, which would return to a value very similar to the simpler scenario described above. Or the gas flows can be altered again to ensure the etch rate does not go above a target value.

As can be seen in FIGS. 4c and 4d, the resultant etched oxide layer 7 is not a direct copy of the mask layer 4 above. The shape and pattern of the etched oxide layer 7 is similar to the mask layer 4 but contracted in the x-y direction. In other words, voids created by the etch process are expanded.

As regions of the oxide layer 7, not protected by the mask layer 4, are removed by the etch and the underlying silicon substrate 3 is exposed, the etch front again starts to change. The exposed surface of the oxide 7 surface in the x-y plane has gone and the etch process continues by etching the oxide 7 directly under the mask layer 4, in other words, undercutting the mask layer 4, see FIGS. 4e and 4f. In terms of the etch front, the area of the etch front decreases, the direction of the etch front transitions from along the z-axis to the x-y plane and the location of the etch front transitions to under the mask layer 4. As such, the etch rate will be lower.

In the undercut etch phase the etch rate has dropped merely because the structure and properties of the etch front have changed. Therefore, the chamber parameters i.e. the etch set-up or etch parameters, can also be changed to match the new conditions encountered by the etch. The pressure can be increased to increase the etch rate. Equally the gas flow ratio can be altered to change the etch rate. Or both the chamber pressure and gas flow ratio can be changed.

The undercut etch is continued until a target state of the microstructure 6 device is achieved, for example, a structure 8 is released, as depicted in FIGS. 4g and 4h.

There are clearly two distinct phases to this etch process: a first initial large open area etch removing material mainly in the z-direction and second a very different undercut etch removing material mainly in the lateral x-y direction. The two etch phases require at least two very different etch set ups, namely etch parameters, to match the region of the structure 8 being etched.

To summarise, FIGS. 4a and 4b depict the MEMS wafer 6 before the isotropic vapour etch. FIGS. 4c and 4d depict the MEMS wafer 6 during a first phase of the isotropic vapour etch. FIGS. 4e and 4f depict MEMS wafer 6 during the transition from the first phase to a second phase of the isotropic vapour etch. FIGS. 4g and 4h depict the MEMS device 6 after the second phase of the isotropic vapour etch.

It will be appreciated that even within these two etch phases the etch front is changing and so the etch process could be further fine-tuned to compensate for the changing etch front. As such, the etch parameters can be considered as being varied as a function of time.

In addition, it will be appreciated that an intermediate phase, alternatively termed transitional phase, in the etch process may be required to transition between the two etch phases as this can require further controlled change.

### Example 2—MEMS Microphone

FIG. 5 depicts a MEMS microphone 36 that, prior to a release etch, has a structure 8 comprising a first, upper polysilicon layer 37, a second, lower polysilicon layer 38 and a first oxide layer 39 sandwiched between the first and second polysilicon layers 37, 38. The MEMS microphone 36 further comprises is a second oxide layer 40 below the second, lower polysilicon layer 38.

The first polysilicon layer 37 comprises a plurality of holes 41 through which an etchant can access the first oxide layer 39. In other words, the plurality of holes 41 expose a surface area 5 of the first oxide layer 39 to an etchant thereby defining an etch front. To release the structure 8 of the MEMS microphone 36, the release etch removes material from the etch front of the first oxide layer 39 in the z direction and then undercuts the first polysilicon layer 37 in the x-y direction. As such, the area, location and direction of the etch front changes as the etch progresses.

After the etch the two polysilicon layers 37, 38 are free to move. However, if the release etch is not controlled, there is the possibility that stiction may occur so that the MEMS microphone 36 may not operate as intended. Furthermore, the MEMS microphone 36 further comprises metal bond pads 42. If the release etch is not controlled, the metal bond pads 42 may exhibit corrosion which would be detrimental to the operation of the MEMS microphone 36.

This structure 8 of the MEMS microphone 36 can be etched in a single phase, in other words using one process set-up with constant parameters. However, there are benefits to changing the etch to a three-phase process.

The first phase comprises etching the MEMS microphone 36, with a high etch rate to ensure a uniform etch initiation across MEMS microphone 36 before the subsequent release of the structure 8. FIG. 5a depicts the MEMS microphone 36 after this first phase. For optimum throughput, this first step should be maximised, but care must be taken not to over etch and prematurely release the structure 8 due to the risk of stiction. In this first phase, the direction of the etch front is predominately in along the z-axis. The area of the etch front increases as the etch starts extending laterally in the x-y plane.

The second phase comprises changing the etch parameters and then performing the release phase of the etch process at a lower etch pressure to achieve a slower etch rate. This second phase is performed until the structure 8 of the MEMS microphone 36 is fully released and the etch front has moved onto undercutting the first polysilicon layer 37, as depicted in FIG. 5b. In this second phase, the area of the etch front decreases, the direction of the etch front is in the x-y plane and the location of the etch front transitions under the polysilicon layer 37.

The third phase comprises again changing the etch parameters and then performing the final phase of the etch process at a higher pressure to achieve a faster etch rate. This third phase results in a lateral etch in the x-y plane further undercutting the first polysilicon layer 37, as depicted in FIG. 5c. It is noted that the second oxide layer 40 is also etched as can be seen in FIG. 5c. In this third phase, the location of the etch front progresses further under the polysilicon layer 37, requiring different etch parameters to maintain the etch rate.

Advantageously, in comparison to a single step process, adopting this three-step process when manufacturing the MEMS microphone is quicker and more efficient whilst minimising the risk of failure, namely due to stiction. The etch set up, namely the parameters are altered to increase or decrease the etch rate accordingly to the level of control required for the structural feature of the MEMS microphone being etched.

### Example 3—Etching Interlevel Dielectric (ILD) in CMOS Multilevel Metal Device

MEMS devices have been manufactured using standard Complementary Method-Oxide-Semiconductor (CMOS) processing to produce sensors using the metallization portion of the structure. An example of such a sensor 43 is depicted in FIG. 6 and can be seen to comprise interlevel dielectric (ILD) layers 44 and metal layers 45. The functionality of the sensor 43 relies on removing interlevel dielectric (ILD) layers 44, which comprise silicon dioxide, by means of an HF vapour etch.

The manufacturing process for the CMOS sensor 43 is designed and optimised to produce high quality electronic devices, and as such to impart the best electronic performance into these devices. In the ongoing effort to produce higher quality devices, the dielectric constant (k) of the ILD should be as low as possible, especially at lower metal levels of the CMOS sensor 43. The silicon dioxide of the ILD layers 44 with low k tend to be much easier to etch, in other words more readily etched, in comparison to a standard oxide film for same etching parameters.

As an etch process proceeds through the various ILD layers 44 of the CMOS sensor 43, there is a point where the lower ILD layers 44 will start to etch. At this point the etch rate of the lower ILD layers 44 will be higher and if the etch rate becomes too high, issues can arise. To maintain high yield the etch parameters must be adjusted to maintain a desirable edge rate.

Instead of manufacturing the CMOS sensor 43 with a single step process which would require a low etch rate to avoid any issues and so this process would be slow, it is advantageous adopting a multi-step process dependent on which ILD layers 44 are being etched. As such, the etch set up, namely the etch parameters, are altered to increase or decrease the etch rate accordingly which ILD layers 44 are being etched which results in a more efficient process.

### Example 4—XeF₂ Etching of a Microchannel

XeF₂ is a vapour that etches silicon isotopically with high selectivity to silicon over other materials such as silicon oxide, silicon nitride, aluminium and photoresist.

The etch rate is controlled by the XeF₂ partial pressure. The higher the XeF₂ partial pressure, the higher the etch rate.

The XeF₂ source material is solid and sublimates to provide XeF₂ vapour 34. The etching apparatus 10 depicted in FIG. 3 employs a solid source bubbler to contain the source material with a carrier gas flow transporting the XeF₂ vapour 34 to the process chamber. The XeF₂ flow is determined by the carrier gas flow. FIG. 7a depicted the XeF₂ flow as a function of the carrier gas flow. As can be seen, the XeF₂ increases with an increase in the carrier gas flow. However, the relationship between the XeF₂ flow and the carrier gas flow is non-linear. FIG. 7b shows the concentration ratio of the XeF₂ flow to the carrier gas as a function of carrier gas flow. Whilst the relationship between the concentration ratio of XeF₂ flow and carrier gas flow is consistent, it is non-linear. As can been seen the concentration ratio of XeF₂ flow is inversely proportional to at the carrier gas flow.

With no etching taking place, for a given chamber pressure the XeF₂ partial pressure is higher at lower carrier gas flow. However, when a sample is being etched the amount of etching has a large effect on the etching set-up, namely the parameters within the chamber 11.

When there is a small amount of silicon being etched, higher XeF₂ partial pressure can be obtained by running with lower carrier gas flow and higher chamber pressure, and therefore a higher etch rate is achieved. This etch is reaction limited. FIG. 8a shows depicts the relationship between chamber pressure, carrier gas flow and etch rate for a reaction limited XeF₂ etch.

When there is large amount of silicon being etched, the XeF₂ flowing into the chamber is being consumed relatively quickly and the XeF₂ partial pressure is dominated by how quickly the XeF₂ flows into the chamber. In this case the etch is transport limited and the etch rate is higher for higher carrier gas flow and the chamber pressure has a much lower influence. FIG. 8b depicts the relationship between chamber pressure, carrier gas flow and etch rate for a transport limited XeF₂ etch.

As previously stated, it will be appreciated that the process chamber set-up is very dependent on the microstructure being etched.

A microchannel 46 can etched in silicon 47 using XeF₂ vapour. Before proceeding with the XeF₂ etch to form a microchannel 46, there is an initial etch into the silicon 47 to form a trench 48 with polymer sidewalls 49 as depicted in FIG. 9a.

XeF₂ vapour etches the exposed silicon 47 at the base of the trench 48, from which the area of etch front expands to form a microchannel 46 as depicted in FIGS. 9b and 9c. The XeF₂ etch is a purely chemical isotropic vapour etch. The etching process is performed in a vacuum chamber with controlled temperature, gas flow and chamber pressure. The etch progress can be measured by the increase in the radius of the microchannel 46 being formed.

If the XeF₂ vapour etch was performed at constant etch parameters, the volume of silicon etched as a function of time is linear, as depicted by FIG. 10a. In other words, the same volume of silicon is etched for the same time unit and the channel continues to expand.

However, as depicted in FIG. 10b, the change in radius of the etched channel as a function of time, in other words the one-dimensional etch rate, will not be linear. FIG. 10b gives the impression that the etch process is slowing down, which is not the case as the volume of material the etch removes increases with the radius of the microchannel 46.

As will be appreciated it is advantageous for the etch to be characterised by a volumetric etch with time. As such, a more relevant measurement is of the etch rate is μm³ per minute, a three-dimensional etch rate.

As the etch continues the channel gets larger and the area of the etch front increases as the radius increases. However, the area of the etch front increases at a faster rate than the radius which has a large influence on the XeF₂ etch.

In this example, the etch rate is determined primarily by the XeF₂ partial pressure such that the higher the partial pressure the higher the etch rate. The XeF₂ partial pressure in the chamber is controlled by the gas flow and chamber pressure. It is also, highly influenced by the exposed area of silicon 47, namely the relatively size of the etch front. With a relatively small etch front, the etch rate is reaction limited and the etch rate is optimised by a high etch pressure and low XeF₂ flow. With relatively the etch front having a relatively large area, the etch rate is transport limited and the etch rate is optimised by much higher XeF₂ flow. In other words, as the etch channel gets larger the etch changes from one etch regime to the other.

It will be appreciated that if the etch process is performed at constant parameters, whilst the etch will still proceed the process will not be optimised for the changes etching process, namely the evolution of the microchannel 46 and etch front.

Instead, for a given overall etch process time, by defining a given parameter starting and ending value and an incremental change delta, an overall number of steps, n, can be determined along with an individual step time. In this way, the step parameters can be varied or ramped over time throughout the etch. In addition to the etch parameter of interest, it is also possible to change or ramp the actual step times themselves throughout the course of the overall etch process, for additional benefit.

Vapour phase etching of bulk silicon or silicon substrates with XeF₂ typically requires long etch times, particularly if the etch is a three dimensional volumetric etch. By using parametric ramping of the etch parameters, it is possible to achieve significantly higher etch rates than with a conventional single step process and so facilitate reduced etch times. An additional benefit is that this can be affected without using more of the expensive XeF₂ etch precursor.

In this example, as the microchannel 46 gets larger the etch regime changes and the etch rate is determined more by the amount of XeF₂ that can be introduced into the chamber 11. FIG. 11 illustrates various etching recipes and specifically, how the carrier gas flow is increased as a function of time, resulting in higher XeF₂ flow and in turn higher etch rate. As the number of increments in the carrier gas flow increases, the etching process can be optimised to reduce the overall etch time.

The change in etch parameters, namely the specific etch recipe, can be programmed with software of the computer controller 35. This functionality gives the user flexibility to efficiently manage the etch process.

### Etch Monitor and Software

As an optional feature, the etching apparatus 10 may comprise an etch monitor 50. Observing the conditions within the chamber 11 is advantageous in setting the optimum etch parameters. Understanding the microstructure to be etched and the conditions of the initial etch, the etch monitor 50 can be used to gauge the progression of the etch and verify what stage or phase the etch is at and adapt the etch conditions during each phase appropriately. The etch monitor 50 may be used to adapt the etch conditions continuously throughout the etch as well as in relation to distinct phases of the etch.

The etch monitor 50 can take the form of a detector that measures the amount infrared light transmitted across the process chamber 11. The amount of light being detected is then related to the various gas molecules in the chamber 11. Knowing the precise amount of the different gases in the chamber 11 relates to the etch rate of the device.

The etch monitor 50 combined with software can be employed to determine when the etch conditions need to be changed and the recipe moved on to the next step.

With even more detailed understanding of the structural etch and with precise control of the process parameters combined with the feedback from the etch monitor an algorithm can control the etch process completely. The initial conditions are set to optimize the starting etch. The etch monitor 50 continually observes the chamber 11 condition and this feedback is used by the software model to determine the optimum chamber 11 conditions for the chamber 11 at that point. The software maintains control of the etch to complete the etch with etch conditions optimized for the entire etch.

The method of manufacturing a microstructure in accordance with the present invention has numerous advantages over methods known in the art.

A key advantage is that the isotropic vapour etch of the three-dimensional structure is optimised according to the three-dimensional structure. In other words, the isotropic vapour etch is considered in a three-dimensional manner as opposed to a one-dimensional manner. Different phases of the isotropic vapour etch can control the volumetric etch rate which varies due to changes in the etch front and or compositional variation in the sacrificial material.

In practice, the isotropic vapour etch can advantageously be utilised to more efficiently create microstructures, whilst minimising the risk of failure of the device. For example, the volumetric etch rate can be slowed when releasing the three-dimensional structure of a MEMS device to avoid stiction and then increased once the three-dimensional structure is released to decrease the manufacture time. As another example, when manufacturing a microchannel, the volumetric etch rate can be changed to accommodate a change from a reaction to transport etch regime.

A method of manufacturing a microstructure a microstructure with a three-dimensional structure is described. The method comprises performing an isotropic vapour etch of a sacrificial material. The etch parameters of the isotropic vapour etch are varied as a function of time responsive to (or based on) prior knowledge of the microstructure. The method has numerous advantages as can more efficiently create microstructures whilst minimising the risk of failure of the device.

The foregoing description of the invention has been presented for the purposes of illustration and description and is not intended to be exhaustive or to limit the invention to the precise form disclosed. The described embodiments were chosen and described in order to best explain the principles of the invention and its practical application to thereby enable others skilled in the art to best utilise the invention in various embodiments and with various modifications as are suited to the particular use contemplated. Therefore, further modifications or improvements may be incorporated without departing from the scope of the invention as defined by the appended claims.

1. A method of manufacturing a microstructure,
the method comprising performing an isotropic vapour etch of a sacrificial material,
wherein etch parameters of the isotropic vapour etch are varied as a function of time according to a process recipe determined before starting the isotropic vapour etch responsive to prior knowledge of the microstructure, and
where the process recipe is unchanged during the isotropic vapour etch.

2. The method of manufacturing a microstructure as claimed in claim 1, wherein the prior knowledge of the microstructure comprises prior knowledge of changes in area, and/or location, and or direction of an etch front of the isotropic vapour etch, and/or compositional variation in the sacrificial material being etched.

3. (canceled)

4. The method of manufacturing a microstructure as claimed claim 1, wherein the isotropic vapour etch comprises:
a first phase at a first set of etch parameters for a first period of time to etch the sacrificial material at a first volumetric etch rate; and
a second phase at a second set of etch parameters for a second period of time to further etch the sacrificial material at a second volumetric etch rate.

5. The method of manufacturing a microstructure as claimed in claim 4, wherein the first and second volumetric etch rates are dependent on different features of the microstructure.

6. The method of manufacturing a microstructure as claimed in claim 4, wherein the first set of etch parameters are different to the second set of etch parameters, and/or the first period of time is different to the second period of time.

7. The method of manufacturing a microstructure as claimed in claim 4, wherein the etch parameters varied between first and second phases comprise pressure, gas flow rates, gas flow ratios, gas species and or temperature.

8. (canceled)

9. The method of manufacturing a microstructure as claimed in claim 4, wherein the first volumetric etch rate and the second volumetric etch rate are maintained below a threshold value by fixing the first and second etch parameters from the outset such that the highest possible etch rate is below the threshold value.

10-12. (canceled)

13. The method of manufacturing a microstructure as claimed in claim 4, wherein the first phase of the isotropic vapour etch corresponds to removing sacrificial material not covered by a mask layer.

14. The method of manufacturing a microstructure as claimed in claim 4, wherein the second phase of the isotropic vapour etch corresponds to removing sacrificial material under the mask layer.

15. The method of manufacturing a microstructure as claimed in claim 4, wherein the isotropic vapour etch further comprises a third phase at a third set of etch parameters for a third period of time to further etch the sacrificial material at a third volumetric etch rate.

16. The method of manufacturing a microstructure as claimed in claim 15, wherein the third phase of the isotropic vapour etch may correspond to removing further sacrificial material under the mask layer.

17. The method of manufacturing a microstructure as claimed in claim 4, wherein the second phase of the isotropic vapour etch corresponds to removing sacrificial material with a different density or readiness to etching in comparison to the sacrificial material removed in the first phase of the isotropic vapour etch.

18. The method of manufacturing a microstructure as claimed in claim 4, wherein the first phase of the isotropic vapour etch may correspond to removing sacrificial material in a reaction limited etching regime.

19. The method of manufacturing a microstructure as claimed in claim 18, wherein the first etch parameters comprise a relatively high etchant partial pressure by operating with a lower carrier gas flow and higher chamber pressure.

20. The method of manufacturing a microstructure as claimed in claim 18, wherein the second phase of the isotropic vapour etch may correspond to removing sacrificial material in a transport limited etching regime.

21. The method of manufacturing a microstructure as claimed in claim 20, wherein the second etch parameters comprise a relatively high etchant flow.

22. The method of manufacturing a microstructure as claimed in claim 18, wherein the first and second phases of the isotropic vapour etch comprises substantially the same or similar volumetric etch rate.

23. The method of manufacturing a microstructure as claimed in claim 1, wherein the isotropic vapour etch comprises a plurality of phases, each phase corresponding to an incremental change in the etch parameters and or period of time.

24. The method of manufacturing a microstructure as claimed in claim 1, wherein the etchant is HF vapour and the sacrificial material is silicon dioxide and or the etchant is XeF₂ and the sacrificial material is silicon.

25. (canceled)

26. The method of manufacturing a microstructure as claimed in claim 1, Wherein the microstructure may be a semiconductor device, a CMOS Semiconductor, a MEMS device, a MEMS microphone or a microchannel.

27. (canceled)
